(19) United States
(12) Patent Application Publication
(10) Pub. No.: US 2015/0303279 A1
(43) Pub. Date: Oct. 22, 2015

(54) Method of Forming Tungsten Nitride Layer of Tungsten Gate

(71) Applicant: Semiconductor Manufacturing International (Shanghai) Corporation, Shanghai (CN)

(72) Inventor: Li Jiang, Shanghai (CN)

(21) Appl. No.: 14/671,987

(22) Filed: Mar. 27, 2015

(30) Foreign Application Priority Data
Apr. 21, 2014 (CN) 201410160807.1

(51) Int. Cl. H01L 29/66; H01L 21/02; H01L 21/3105; H01L 21/285; H01L 29/423; H01L 21/3213; H01L 21/28

(52) U.S. Cl. CPC H01L 29/66545; H01L 21/32133; H01L 21/0217; H01L 21/28088; H01L 21/28568; H01L 21/28556; H01L 29/42372; H01L 21/31055

(57) ABSTRACT

A method for manufacturing a semiconductor device includes providing a front-end device containing a dummy gate, removing the dummy gate, and forming a gate structure including a tungsten gate in a location previously occupied by the dummy gate that has been removed. The method also includes etching back a portion of the tungsten gate, forming a laminate structure having at least one layer of tungsten and one layer of tungsten nitride on the etched back tungsten gate, and forming a silicon nitride cap layer on the laminate structure.

### CROSS-REFERENCES TO RELATED APPLICATIONS

This application claims priority to Chinese patent application No. 201410160807.1, filed on Apr. 21, 2014, the content of which is incorporated herein by reference in its entirety.

### BACKGROUND OF THE INVENTION

The present invention relates to semiconductor devices, and more particularly to a method for fabricating a semiconductor device.

In the field of semiconductor technology of 20 nm process technology nodes and below, tungsten (W) is replacing aluminum (Al) as the gate material for a semiconductor device when taking into consideration the gap fill capabilities and device performance, a chemical mechanical polishing (CMP) process is used to form the tungsten metal gate structure. As critical dimensions shrink, when a self-aligned contact hole process is used, a mis-alignment will lead to the possibility of a bridging between the contact hole and the tungsten gate. In order to avoid the bridging problem, after performing the CMP process for forming the tungsten metal gate structure, an etching back process is carried out to etch the tungsten metal gate structure, then a silicon nitride film (SiN) is deposited on the etched back tungsten metal gate structure, and a CMP process is performed on the silicon nitride film to form a silicon nitride cap layer. However, since the adhesion force between tungsten and silicon nitride is relatively weak, the silicon nitride cap layer may peel off (delamination) during the CMP process.

Referring to FIGS. 1A to 1E, a method of the prior art may include the following steps:

Step E1: provide a front-end device containing a dummy gate, remove the dummy gate, deposit a work function metal layer (not shown) and a tungsten film in the original location of the removed dummy gate, then perform a CMP process on the tungsten film to form a tungsten gate 101. An intermediate structure is obtained, as shown in FIG. 1A.

The dummy gate may be polysilicon or other suitable materials. Front-end device 100 ay typically include a semiconductor substrate, a dielectric layer on the semiconductor substrate, the dummy gate, gate sidewalls, an interlayer dielectric layer, and the like.

Step E2: remove a certain thickness of the tungsten gate 101 using an etching back process, as shown in FIG. 1B.

Step E3: deposit a silicon nitride film 1020 on tungsten gate 101, as shown in FIG. 1C.

Step E4: perform a CMP process on silicon nitride film 1020 to remove the excess silicon nitride film to form a silicon nitride cap layer 102 on tungsten gate 101, as shown in FIG. 1D. FIG. 1D illustrates a desired semiconductor device structure in the manufacturing process.

However, since adhesion between tungsten (i.e., tungsten gate 101) and silicon nitride (i.e., silicon nitride film 1020) is relatively poor, delamination (peeling off) of silicon nitride film 1020 may generally occur when a CMP process is performed on silicon nitride film 1020, so that silicon nitride cap layer 102 is removed during the CMP process resulting in the structure as shown in FIG. 1E, that leads to decreased yields of semiconductor devices.

Many attempts have been made to deposit an adhesive between the tungsten gate and the silicon nitride layer. However, the deposited adhesive often leads to bridging of the sidewalls during formation of self-aligned contact holes, which adversely affects the yield of the semiconductor devices.

In view of the foregoing, there is a need for a novel method for manufacturing a semiconductor device that can overcome the deficiencies of the prior art.

### BRIEF SUMMARY OF THE INVENTION

Embodiments of the present invention provide a method for manufacturing a semiconductor device

In accordance with the present invention, a method for manufacturing a semiconductor device includes providing a front-end device comprising a dummy gate, removing the dummy gate, forming a gate structure comprising a tungsten gate in a location previously occupied by the dummy gate that has been removed (S101), etching back a portion of the tungsten gate (S102), forming a laminate structure comprising at least one layer of tungsten and one layer of tungsten nitride on the etched back tungsten gate (S103), and forming a silicon nitride cap layer on the laminate structure (S104).

In an embodiment, forming the laminate structure includes forming a boron-containing sacrificial layer on the etched back tungsten gate (S1031), exposing the boron-containing sacrificial layer to a tungsten-containing precursor to form a tungsten metal layer on a top surface of the etched back tungsten gate (S1032), and exposing the tungsten metal layer to a nitrogen-containing gas to form a tungsten nitride layer (S1033).

In an embodiment, forming the boron-containing sacrificial layer includes depositing a boron-containing gas on the etched back tungsten gate. The boron-containing gas may include B₂H₆. The boron-containing sacrificial layer has a thickness in a range between 3 Angstroms and 20 Angstroms. The boron-containing sacrificial layer may be formed at a temperature in the range between 200° C. and 400° C.

In an embodiment, the tungsten-containing precursor includes any one or a combination of at least two of WF₆, WCl₆, and W(CO)₆. The nitrogen-containing gas includes any one or a combination of at least two of N₂, NH₃, NF₃, and N₂H₆.

In an embodiment, the method may further include, after exposing the tungsten metal layer to the nitrogen-containing gas to form the tungsten nitride layer, repeating at least once the steps of forming a new boron-containing sacrificial layer on the tungsten gate, exposing the new boron-containing sacrificial layer to the tungsten-containing precursor to form a new tungsten metal layer on the tungsten gate, and exposing the new tungsten metal layer to the nitrogen-containing gas to form a new tungsten nitride layer.

In an embodiment, the method also includes forming a work function metal layer prior to forming the tungsten gate, forming a tungsten film on the work function layer (e.g., using a chemical vapor deposition process), and performing a chemical mechanical polishing (CMP) process on the tungsten film to form the tungsten gate.

In an embodiment, the work function metal layer may include one of the TiN, TaAl, TiN, AlCo, TiAlN.

In an embodiment, etched back portion of the tungsten gate has a thickness (depth) in the range between 200 Angstroms and 400 Angstroms.

In an embodiment, the silicon nitride cap layer may be formed by depositing a silicon nitride film on the laminate structure (S1041), and performing a CMP process on the silicon nitride film to form a silicon nitride cap layer (S1042).

The following description, together with the accompanying drawings, will provide a better understanding of the nature and advantages of the claimed invention.

### BRIEF DESCRIPTION OF THE DRAWINGS

FIGS. 1A to 1E are cross-sectional views depicting stages of a method of manufacturing a semiconductor device according to the prior art;

FIG. 2A to 2E are partial cross-sectional views depicting stages of a method of manufacturing a semiconductor device according to one embodiment of the present invention; and

FIG. 3 is a simplified flow chart of a method of manufacturing a semiconductor device according to one embodiment of the present invention.

### DETAILED DESCRIPTION OF THE INVENTION

In the following description, numerous specific details are provided for a thorough understanding of the present invention. However, it should be appreciated by those of skill in the art that the present invention may be realized without one or more of these details. In other examples, features and techniques known in the art will not be described for purposes of brevity.

It should be understood that the drawings are not drawn to scale, and similar reference numbers are used for representing similar elements. Embodiments of the invention are described herein with reference to cross-section illustrations that are schematic illustrations of idealized embodiments (and intermediate structures) of the invention. The thickness of layers and regions in the drawings may be exaggerated relative to each other for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

It will be understood that, when an element or layer is referred to as “on,” “disposed on,” “adjacent to,” “connected to,” or “coupled to” another element or layer, it can be disposed directly on the other element or layer, adjacent to, connected or coupled to the other element or layer, or intervening elements or layers may also be present. In contrast, when an element is referred to as being “directly on,” directly disposed on,” “directly connected to,” or “directly coupled to” another element or layer, there are no intervening elements or layers present between them. It will be understood that, although the terms “first,” “second,” “third,” etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Relative terms such as “under,” “below,” “underneath,” “over,” “overlying”, “on,” “above,” “bottom,” and “top” are used herein to described a relationship of one element, layer or region to another element, layer or region as illustrated in the figures. It will be understood that these terms are intended to encompass different orientations of the structure in addition to the orientation depicted in the figures. For example, if the device shown in the figures is flipped, the description of an element being “below” or “underneath” another element would then be oriented as “above” the other element. Therefore, the term “below,” “under,” or “underneath” can encompass both orientations of the device. Because devices or components of embodiments of the present invention can be positioned in a number of different orientations (e.g., rotated 90 degrees or at other orientations), the relative terms should be interpreted accordingly.

The terms “a”, “an” and “the” may include singular and plural references. will be further understood that the terms “comprising”, “including”, having” and variants thereof when used in this specification, specify the presence of stated features, steps, operations, elements, and/or components, but do not preclude the presence or addition of one or more other features, steps, operations, elements, components, and/or groups thereof. Furthermore, as used herein, the words “and/or” may refer to and encompass any possible combinations of one or more of the associated listed items.

The use of the terms first, second, etc. do not denote any order, but rather the terms first, second, etc. are used to distinguish one element from another. Furthermore, the use of the terms a, an, etc. does not denote a limitation of quantity, but rather denote the presence of at least one of the referenced items.

The term “vertical” as used in this application is defined as a plane perpendicular to the conventional plane or surface of a wafer or substrate, regardless of the orientation of the wafer or substrate. The term “horizontal” refers to a direction perpendicular to the vertical as defined above.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a discrete change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Prepositions, such as “on”, “side” (as in “sidewall”), “below”, “above”, “higher”, “lower”, “over” and “under” are defined with respect to the conventional plane or surface being on the top surface of the wafer or substrate, regardless of the orientation of the wafer or substrate. It will be understood that these terms are intended to encompass different orientations of the device in addition to the orientation depicted in the figures.

The present invention will now be described more fully herein after with reference to the accompanying drawings, in which preferred embodiments of the invention are shown. This invention may, however, be embodied in many different forms and should not be construed as limited by the embodiments set forth herein.

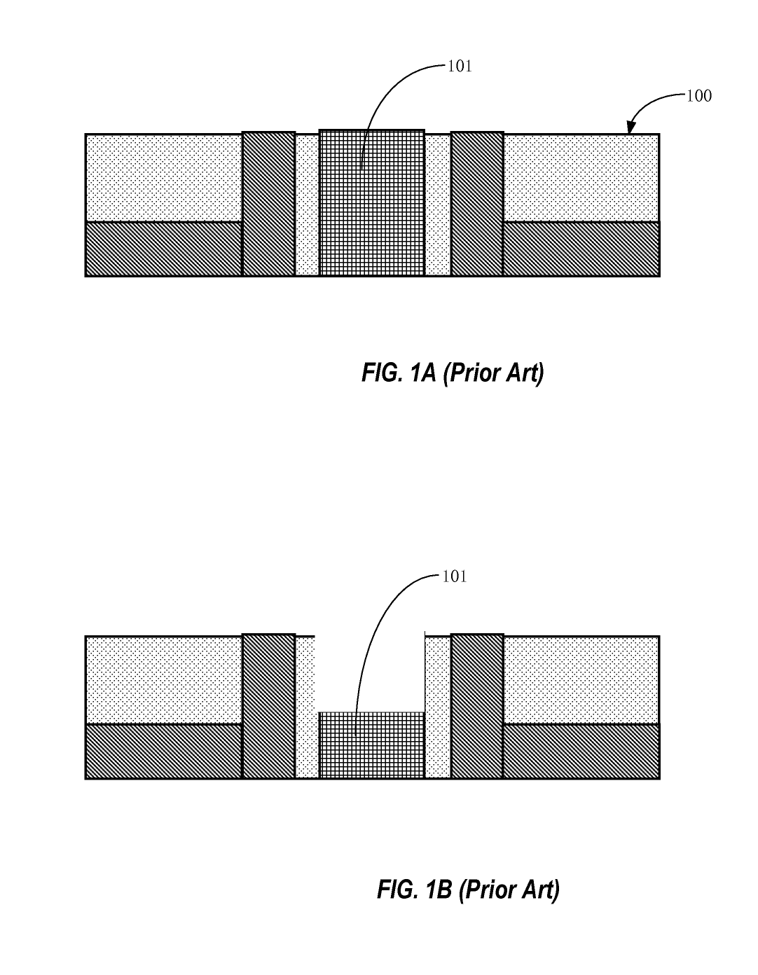

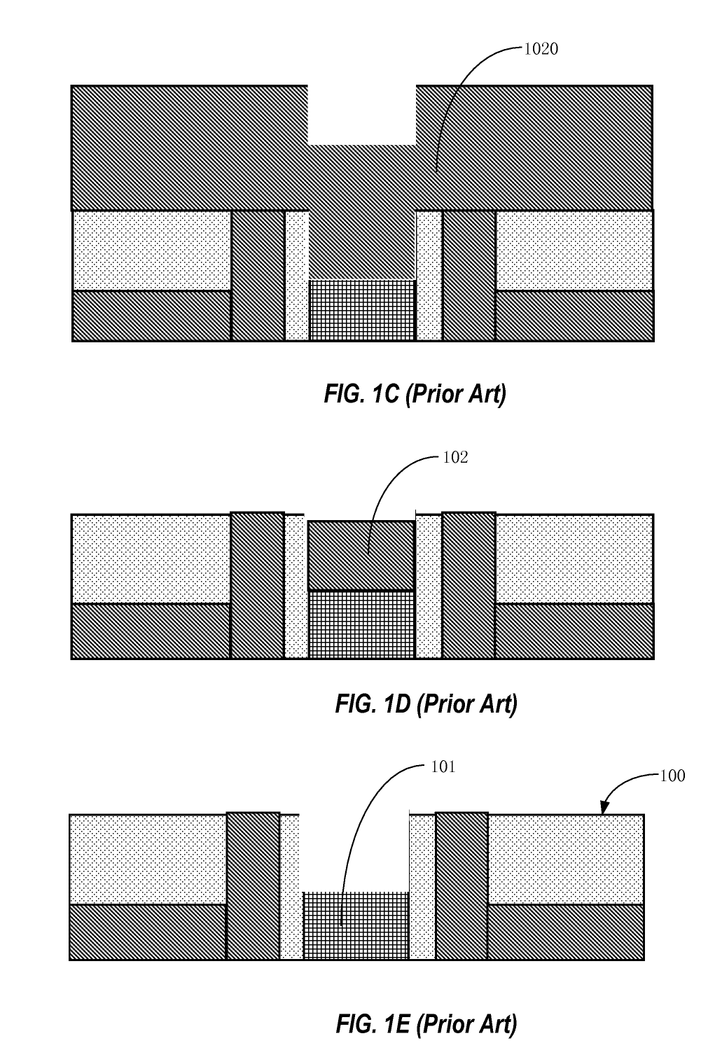

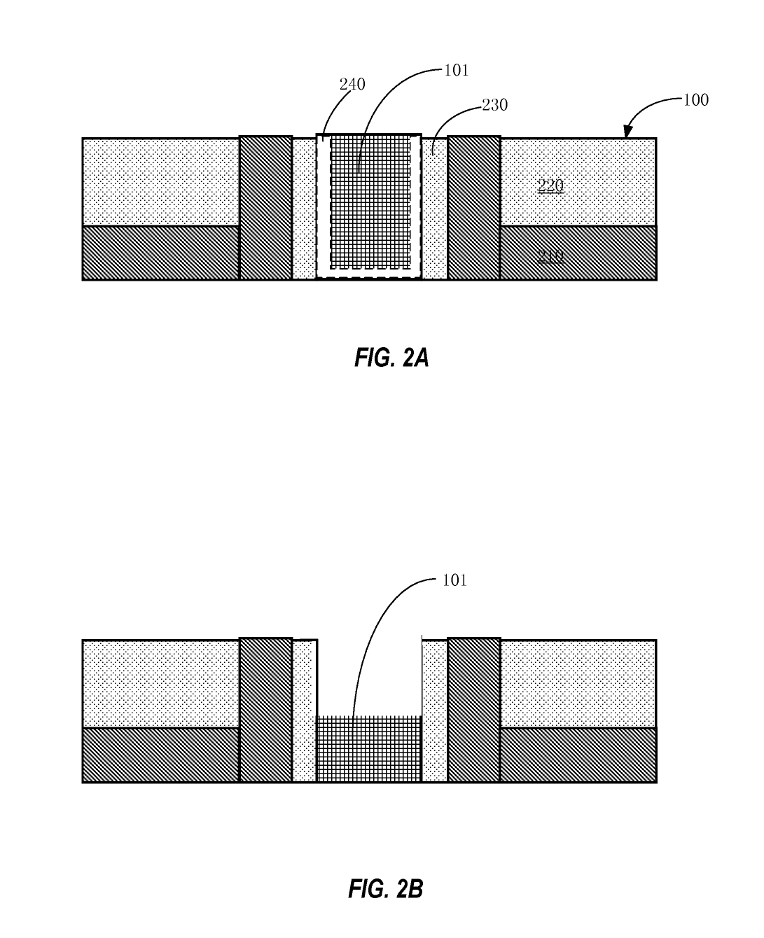

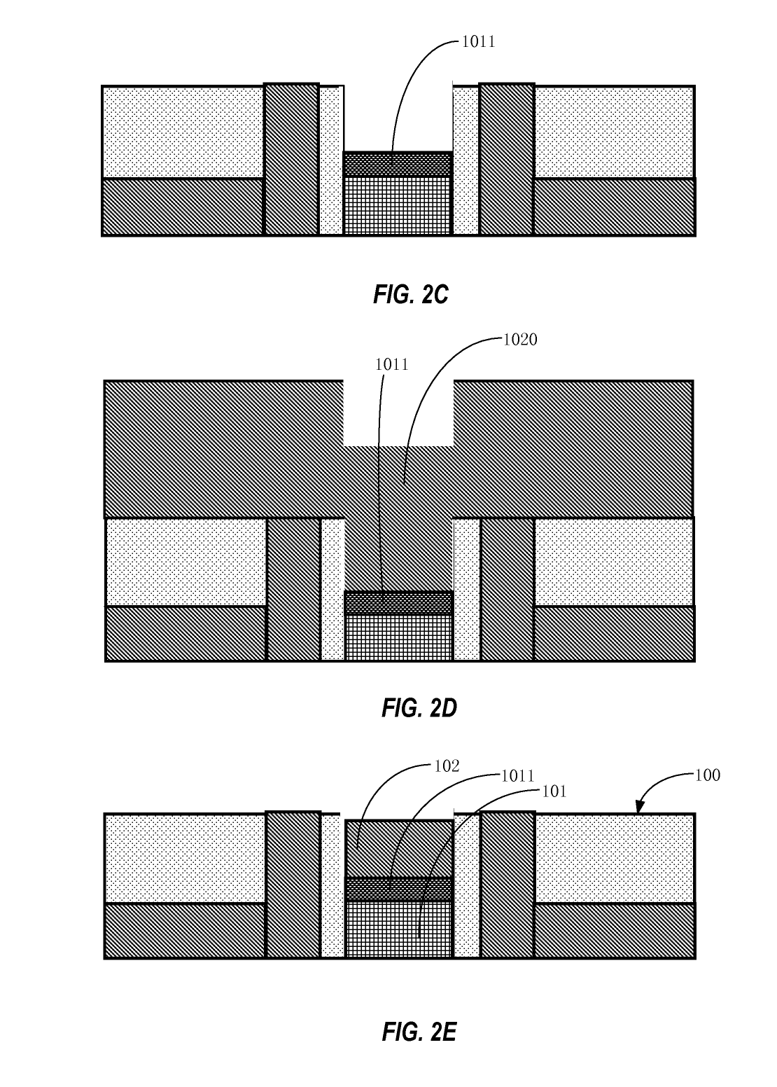

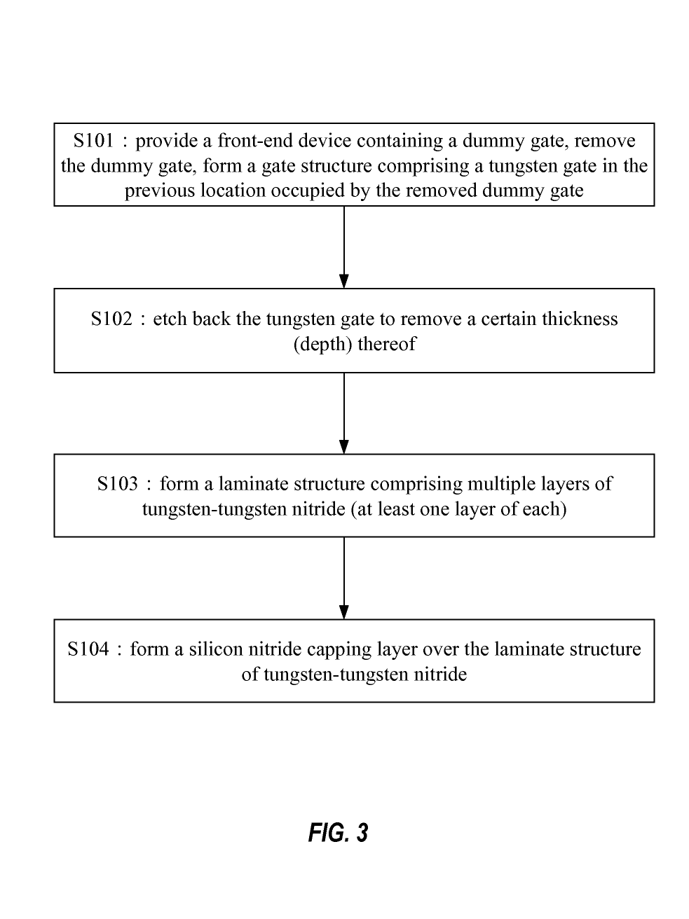

FIGS. 2A to 1E are simplified cross-sectional views illustrating process steps of forming a semiconductor device according to one embodiment of the present invention. FIG. 3 is a simplified flow chart of a method of fabricating a semiconductor device according to one embodiment of the present invention.

With reference to FIGS. 2A to 1E and FIG. 3, a method of fabricating a semiconductor device may include the following steps:

Step A1: provide a front-end device 100 comprising a dummy gate; remove the dummy gate, and deposit a work function metal layer (indicated as dashed line 240 in FIG. 2A) and a tungsten film on the work function metal layer at the original location previously occupied by the dummy gate that has been removed. The term “front-end device” is defined herein as the first portion of a semiconductor device process where one or more components (transistors, capacitors, resistors, diodes, etc.) are formed in and/or on a semiconductor substrate before the devices are interconnected with wiring layers.

The tungsten film may be deposited using a chemical vapor deposition process.

Step A2: perform a CMP process on the tungsten film to form a tungsten gate 101.

After steps A1 and A2, an intermediate structure is obtained as shown in FIG. 2A.

In an embodiment, the dummy gate may include polysilicon or other suitable materials. The work function metal layer (not shown) may be selected from one of the TiN, TaAl, TiN, AlCo, TiAlN. Front-end device 100 may typically include a semiconductor substrate 210, a gate dielectric layer 220 on the semiconductor substrate, the above described dummy gate that is to be removed and replaced with the tungsten gate 101, gate sidewalls or spacers 230, an interlayer dielectric layer, and other components including conventional structures.

Step A3: etch back tungsten gate 101 to remove a certain thickness (a top portion) of tungsten gate 101, as shown in FIG. 2B.

In an embodiment, the removed thickness (height, depth) of the tungsten gate 101 is about 200 Angstroms to 400 Angstroms.

Step A4: form a boron-containing sacrificial layer on the tungsten gate 101.

In an embodiment, the boron-containing sacrificial layer is formed by depositing a boron-containing gas on the tungsten gate whose top portion has been removed (or by applying a boron-containing gas on the tungsten gate to the surface of the top surface of the tungsten gate).

In an embodiment, the boron-containing gas may be diborane (B₂H₆) or other suitable gases with similar characteristics. The boron-containing sacrificial layer may have a thickness in the range between 3 and 20 Angstroms, the reaction temperature during the formation of the boron-containing sacrificial layer may be in the range between 200° C. to 400° C.

In an embodiment, the boron-containing sacrificial layer is formed mainly used to form a reducing environment, which can restore tungsten from a tungsten-containing gas to form a new tungsten metal layer on tungsten gate 101. The tungsten metal layer thus formed according to the embodiment has a microstructure that is different from the conventionally formed (e.g., by chemical vapor deposition) tungsten gate 101, which can reacted easily with N₂, NH₃, NF₃ and N₂H₆ for forming tungsten nitride.

Step A5: expose the boron-containing sacrificial layer to a tungsten-containing precursor to form a tungsten metal layer on tungsten gate 101.

In an embodiment, the tungsten-containing precursor may be any one or a combination of at least two of WF₆, WCl₆, and W(CO)₆.

Since the boron-containing sacrificial layer includes a reducing agent (i.e., formed in a reducing environment), the boron-containing sacrificial layer may react with the tungsten-containing precursor, thereby restoring tungsten from the tungsten-containing precursor to form a new tungsten metal layer on the tungsten gate 101. Furthermore, the tungsten metal layer has a microstructure that is different from that of tungsten gate 101, so that the tungsten metal layer can easily react with N₂, NH₃, and NF₃ and N₂H₆ and other gases to form a tungsten nitrite.

Step A6: expose the tungsten metal layer to a nitrogen-containing gas (a nitriding agent) in order to nitride a portion of the tungsten metal layer, thereby forming a tungsten-tungsten nitride (W-WN) laminate structure 1011.

In an embodiment, the nitrogen-containing gas (a nitriding agent) may be any one or a combination of at least two of N₂, NH₃, NF₃ and N₂H₆.

Since the tungsten metal layer has a microstructure that is different from that of tungsten gate 101, the tungsten metal layer can easily react with N₂, NH₃, NF₃ and N₂H₆ and other gases to form a tungsten nitride. Thus, by forming a tungsten metal layer and nitriding a portion of the tungsten metal layer, a laminate structure of tungsten (W) and tungsten nitride (WN) can be formed (a bilayer of W-WN).

Through steps A4 to A6, an intermediate structure will be obtained as shown in FIG. 2C.

In the embodiment, laminate structure 1011 is formed only on the top surface of the tungsten gate 101 and not on the surface of the sidewalls, as shown in FIG. 2C.

Step A7: deposit a silicon nitride film 1020 on laminate structure 1011, as shown in FIG. 2D.

Step A8: perform a CMP process on silicon nitride film 1020 to remove excess of the silicon nitride film from the top surface of front-end device 100 to form a silicon nitride cap layer 102 covering the top surface of tungsten gate 101, as shown in FIG. 2E.

Because of the presence of W-WN laminate structure 1011 between tungsten gate 101 and silicon nitride cap layer 102, the adhesion force between W-WN laminate structure 1011 and tungsten gate 101 and the adhesion force between W-WN laminated structure 1011 and silicon nitride cap layer 102 are stronger than the adhesion force of the direct contact between tungsten gate 101 and silicon nitride cap layer 102, therefore, delamination (peeling off) of silicon nitride film 1020 will not occur during the CMP process, thereby ensuring the yield of the semiconductor device.

In an embodiment, step A67 may be added between steps A6 and A7, which includes repeating steps A4 through A6 at least once to form a laminate structure having multiple layers (at least two layers) of tungsten-tungsten nitride, thereby further improving the adhesion force between the top surface of tungsten gate 101 and the bottom surface of silicon nitride cap layer 102.

This completes the description of the main steps of the method for manufacturing a semiconductor device according to the present invention. After step A8, other steps may be added to finalize the manufacture of the semiconductor device.

In accordance with the present invention, after etching back tungsten gate 101 and prior to forming silicon nitride cap layer 102 on tungsten gate 101, a tungsten-tungsten nitride laminate structure is formed on tungsten gate 101 to improve the adhesion between tungsten gate 101 and silicon nitride cap layer 102 to prevent lamination of silicon nitride cap layer 102 during the CMP process, thereby improving the yield of the semiconductor device.

FIG. 3 is a simplified flow chart of a method of manufacturing a semiconductor device according to one embodiment of the present invention. The method may include:

S101: provide a front-end device comprising a dummy gate; remove the dummy gate; and form a gate structure comprising a tungsten gate in the previous location of the dummy gate that has been removed (FIG. 2A);

S102: etch back a top portion of the tungsten gate (FIG. 2B);

S103: form a laminate structure comprising multiple layers of tungsten and tungsten nitride (at least one layer of tungsten and one layer of tungsten nitride) on the tungsten gate (FIG. 2C);

S104: form a silicon nitride cap layer on the laminate structure of multiple layers of tungsten-tungsten nitride (FIG. 2E).

In an embodiment, step 103 may include:

Step S1031: form a boron-containing sacrificial layer on the etched back tungsten gate;

Step S1032: expose the boron-containing sacrificial layer to a tungsten-containing precursor to form a tungsten metal layer on a top surface of the etched back tungsten gate;

Step S1033: expose the tungsten metal layer to a nitrogen-containing gas to form a tungsten nitride layer.

In an embodiment, step S1031 includes depositing a boron-containing gas on the etched back tungsten gate (or applying a boron-containing gas to the etched back tungsten gate). The boron-containing gas includes B₂H₆. The boron-containing sacrificial layer is formed at a reaction temperature between 200° C. and 400° C.

In an embodiment, the boron-containing sacrificial layer has a thickness in the range between 3 Angstroms and 20 Angstroms.

In an embodiment, the tungsten-containing precursor in step S1032 includes any one or a combination of at least two of WF₆, WCl₆, and W(CO)₆.

In an embodiment, the nitrogen-containing gas any one or a combination of at least two of N₂, NH₃, NF₃, and N₂H₆.

In an embodiment, the method further includes, after step S1033, repeating at least steps S1031 through S1033 at least once to form multiple alternate layers of tungsten-tungsten nitride.

In an embodiment, the gate structure may include a work function metal layer disposed below the tungsten gate. The gate structure in step S101 may be formed by removing the dummy gate, forming a work function metal layer in the previous location of the dummy gate that has been removed, forming a tungsten film on the work function metal layer (e.g., using a chemical vapor deposition process), and performing a CMP process to remove excess of the tungsten film that is over the original height of the dummy gate.

In an embodiment, the work function metal layer includes one of the TiN, TaAl, TiN, AlCo, TiAlN.

In an embodiment, the silicon nitride cap layer is formed by depositing a silicon nitride film on the laminate structure, and performing a CMP process on the silicon nitride film.

While the present invention is described herein with reference to illustrative embodiments, this description is not intended to be construed in a limiting sense. Rather, the purpose of the illustrative embodiments is to make the spirit of the present invention be better understood by those skilled in the art. In order not to obscure the scope of the invention, many details of well-known processes and manufacturing techniques are omitted. Various modifications of the illustrative embodiments as well as other embodiments will be apparent to those of skill in the art upon reference to the description. For example, although one tungsten gate is used, it is understood that the number of the tungsten gates can be more than one in other embodiments. It is therefore intended that the appended claims encompass any such modifications.

Furthermore, some of the features of the preferred embodiments of the present invention could be used to advantage without the corresponding use of other features. As such, the foregoing description should be considered as merely illustrative of the principles of the invention, and not in limitation thereof

What is claimed is:

1. A method for manufacturing a semiconductor device, the method comprising:
providing a front-end device comprising a dummy gate;
removing the dummy gate;
forming a gate structure comprising a tungsten gate in a location previously occupied by the dummy gate that has been removed;
etching back a portion of the tungsten gate;
forming a laminate structure comprising at least one layer of tungsten and one layer of tungsten nitride on the etched back tungsten gate; and
forming a silicon nitride cap layer on the laminate structure.

2. The method of claim 1, wherein forming the laminate structure comprises:
forming a boron-containing sacrificial layer on the etched back tungsten gate;
exposing the boron-containing sacrificial layer to a tungsten-containing precursor to form a tungsten metal layer on a top surface of the etched back tungsten gate; and
exposing the tungsten metal layer to a nitrogen-containing gas to form a tungsten nitride layer.

3. The method of claim 2, wherein forming the boron-containing sacrificial layer comprises depositing a boron-containing gas on the etched back tungsten gate.

4. The method of claim 3, wherein the boron-containing gas comprises B₂H₆.

5. The method of claim 2, wherein the boron-containing sacrificial layer has a thickness in a range between 3 Angstroms and 20 Angstroms.

6. The method of claim 2, wherein forming the boron-containing sacrificial layer is performed under a temperature in a range between 200° C. and 400° C.

7. The method of claim 2, wherein the tungsten-containing precursor comprises any one or a combination of at least two of WF₆, WCl₆, and W(CO)₆.

8. The method of claim 2, wherein the nitrogen-containing gas comprises any one or a combination of at least two of N₂, NH₃, NF₃, and N₂H₆.

9. The method of claim 2, further comprising, after exposing the tungsten metal layer to the nitrogen-containing gas to form the tungsten nitride layer, repeating the steps of claim 2 at least once to form a plurality of stacked tungsten layers and tungsten nitride layers.

10. The method of claim 1, further comprising:
forming a work function metal layer below the tungsten gate.

11. The method of claim 10, further comprising:
forming a tungsten film on the work function layer;
performing a chemical mechanical polishing (CMP) process on the tungsten film to form the tungsten gate.

12. The method of claim 11, wherein forming the tungsten film comprises a chemical vapor deposition process.

13. The method of claim 10, wherein the work function metal layer comprises one of the TiN, TaAl, TiN, AlCo, TiAlN.

14. The method of claim 1, wherein the etched back portion of the tungsten gate has a thickness in a range between 200 Angstroms and 400 Angstroms.

15. The method of claim 1, wherein forming the silicon nitride cap layer comprises:
depositing a silicon nitride film on the laminate structure; and
performing a CMP process on the silicon nitride film.
